(19) United States
(12) Patent Application Publication
(10) Pub. No.: US 2007/0232043 A1
(43) Pub. Date: Oct. 4, 2007

(54) Method for forming thermal stable silicide using surface plasma treatment

(75) Inventors: Jyh-Huei Chen, Hsinchu (TW); Mei-Yun Wang, Hsinchu (TW); Tze-Liang Lee, Hsinchu (TW)

Correspondence Address: BIRCH, STEWART, KOLASCH & BIRCH, LLP, PO BOX 747, 8110 GATEHOUSE RD, STE 500 EAST, FALLS CHURCH, VA, 22040-0747, US

(73) Assignee: TAIWAN SEMICONDUCTOR MANUFACTURING CO., LTD.

(21) Appl. No.: 11/395,212

(22) Filed: Apr. 3, 2006

(51) Int. Cl. H01L 21/4763

(52) U.S. Cl. 438/592

(57) ABSTRACT

A method for forming a silicide layer on a substrate. A substrate with a silicon surface is provided. Nitrogen is incorporated into the silicon surface by a plasma treatment, to form a nitridized silicon surface. A metal layer is formed on the nitridized silicon surface. The substrate having the metal layer thereon is annealed to form a silicide layer between the metal layer and the substrate.

### BACKGROUND

The present invention relates to a semiconductor process, and particularly to an improved silicide process using a surface plasma treatment.

Advanced photolithography and etching technologies for semiconductor fabrication enable increased density of semiconductor devices and a concomitant increase in device operating speed due to the scaling down of the semiconductor device size. The reduction in dimensions of semiconductor devices, however, causes a corresponding increase in contact resistance, thus an increase in interconnection time delay is incurred, which is an obstacle to realizing higher performance devices. To overcome the increase in interconnection time delay, metal silicide layers are formed on top of the polysilicon gate and doping regions in the silicon substrate to lower the contact resistance thereof and gain increased circuit speed.

A silicide is a refractory metal-silicon composite commonly formed by depositing a refractory metal, such as titanium, cobalt, nickel, platinum, or tantalum, across the upper surface of the silicon. The metal/silicon interface is then heated to form the silicide by reaction of the silicon with the overlying metal. Any nonreacted metal portion is then typically removed leaving only the silicide on the top surface of silicon. The silicide reduces the resistivity of subsequently formed contacts.

A problem in the silicide process, however, is the occurrence of agglomeration of silicide films during annealing. Agglomeration is a condition in which the metal silicide film has discontinuities caused by silicon diffusion and grain growth. As the annealing temperature is raised, silicon within and under the metal silicide diffuses, forming large silicon grains which breaks the continuity of the original metal silicide film. Thus, the average sheet resistance of the agglomerated silicide increases itself.

Thus an improved method for forming low resitivity silicide without agglomeration is desirable.

### SUMMARY

A method for forming a silicide layer on a substrate and a salicide process are provided. An exemplary embodiment of a method for forming a silicide layer on a substrate comprises providing a substrate with a silicon surface. Nitrogen is incorporated into the silicon surface by a plasma treatment, to form a nitridized silicon surface. A metal layer is formed on the nitridized silicon surface. The substrate having the metal layer thereon is annealed to form a silicide layer between the metal layer and the substrate.

An exemplary embodiment of a salicide (self-aligned silicide) process comprises providing a silicon substrate comprising an active region, a silicon gate overlying the active region and a doping region in the active region outside the silicon gate. Nitrogen is incorporated into the silicon gate and the doping region by a plasma treatment, to form nitridized silicon surfaces on the silicon gate and the doping region, respectively. The nitridized silicon surfaces are capped with a conformal metal layer. The substrate having the metal layer thereon is annealed to form silicide layers between the metal layer and silicon gate and between the metal layer and the doping region, respectively.

### BRIEF DESCRIPTION OF THE DRAWINGS

The invention will become more fully understood from the detailed description given hereinbelow and the accompanying drawings, given by way of illustration only and thus not intended to be limitative of the invention.

FIGS. 1A to 1D are cross-sections of an embodiment of a method for forming a silicide layer on a substrate.

FIGS. 2A to 2D are cross-sections of an embodiment of a salicide process.

### DESCRIPTION

As will be appreciated by persons skilled in the art from the discussion herein, the present invention has wide applicability to many manufacturers, factories and industries. For discussion purposes, the embodiments are made herein to semiconductor foundry manufacturing (i.e., wafer fabrication in an IC foundry). However, the present invention is not limited thereto.

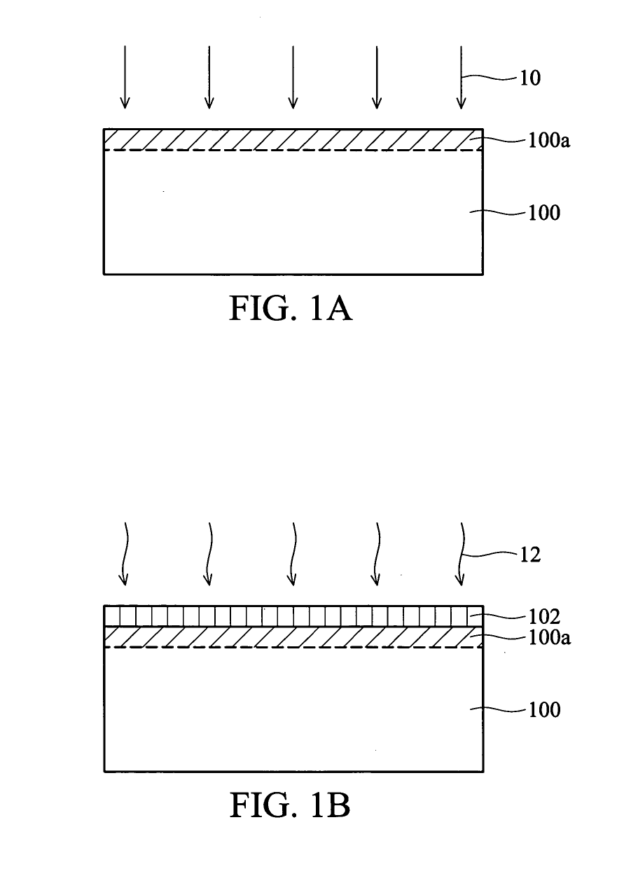

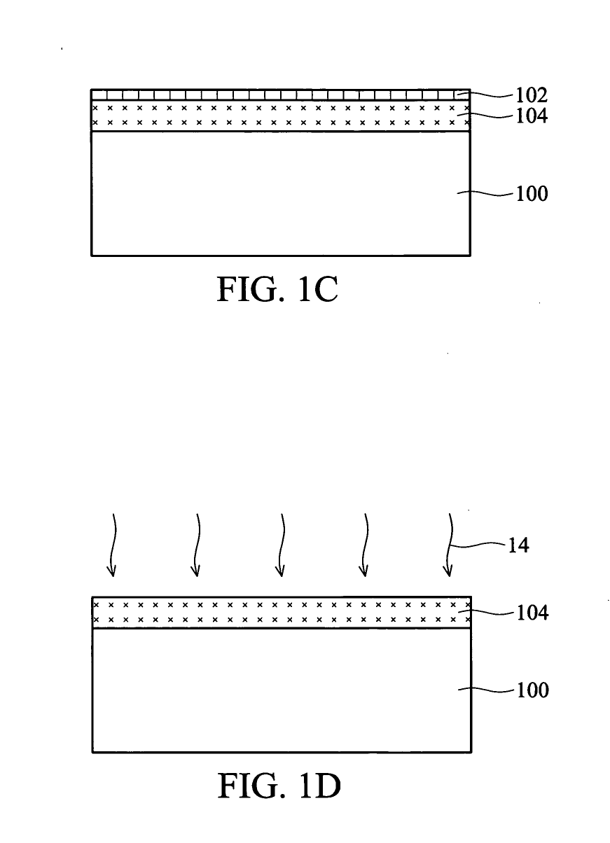

The invention relates to an improved silicide or salicide process. FIGS. 1A to 1D illustrate an embodiment of a method for forming a silicide layer 104 on a substrate 100. In FIG. 1A, a substrate 100 with a silicon surface is provided. The substrate 100 may comprise crystalline silicon, polysilicon, amorphous silicon, SiGe or other semiconductor substrate comprising silicon, such as a SOI substrate. Moreover, the substrate 100 may contain a variety of elements, including, for example, transistors, resistors, and other semiconductor elements as is well known in the art. In order to simplify the diagram, a flat substrate is depicted. Next, the silicon surface of the substrate 100 may be optionally cleaned by conventional dry or wet etching. For example, the silicon surface is cleaned by dipping into a diluted hydrofluoric (HF) solution, removing the native oxide thereon. A surface plasma treatment 10 is subsequently performed on the substrate 100. In this embodiment, the plasma comprises nitrogen, thereby incorporating nitrogen into the silicon surface of the substrate 100 to form a nitridized silicon surface 100a. For example, the silicon surface of the substrate 100 is nitridized by remote plasma nitridation (RPN) or decoupled plasma nitridation (DPN) In this embodiment, the surface plasma treatment 10 is performed using N₂ or N₂O as a process gas having a flow rate of 1 sccm to 1000 sccm. Moreover, the other conditions of surface plasma treatment 10 may comprises a pressure of 10 Torr to 760 Torrs, a temperature of 20° C. to 400° C., a time of 0.01 sec to 600 sec, and a power of 10 W to 1000 W.

In FIG. 1B, the nitridized silicon surface 100a of the substrate 100 is capped with a refractory metal layer 102, such as cobalt or nickel. For example, the refractory metal layer 102 is formed on the nitridized silicon surface 100a of the substrate 100 by conventional deposition, such as sputtering, evaporation or chemical vapor deposition (CVD). In this embodiment, the nitridized silicon surface 100a of the substrate 100 is capped with a cobalt layer having a thickness of 10 Å to 300 Å. After formation of the metal layer 102, a first annealing 12, such as rapid thermal annealing (RPA), is performed on the substrate 100 having the metal layer 102 thereon. In this embodiment, the substrate 100 is annealed at a temperature of 200° C. to 600° C. for 0.01 sec to 300 sec. When the first annealing 12 is completed, a metal silicide layer 104 is formed between metal (cobalt) layer 102 and the substrate 100, as shown in FIG. 1c.

In FIG. 1D, the remaining metal layer 102 (i.e. nonreacted metal layer) on-the metal silicide layer 104 is subsequently removed to expose the surface of-the metal silicide layer 104. In some embodiments, the remaining metal layer 102 may be removed by sulfuric acid, hydrogen peroxide, or other suitable solution used in the art. Finally, a second annealing 14, such as RTA, is performed on the exposed metal silicide layer 104 to stabilize the metal silicide phase thereof or achieve a lower resistivity. For example, if the metal silicide is cobalt silicide, the second annealing 14 is performed thereon to form a cobalt di-silicide (CoSi₂) phase. If the metal silicide is nickel silicide, the second annealing 14 is performed thereon to resist transformation from nickel mono-silicide to higher resistvity nickel di-silicide (NiSi₂). In this embodiment, the metal silicide layer 104 may be a cobalt silicide layer and be annealed at a temperature of 600° C. to 900° C. for 0.01 sec to 180 sec.

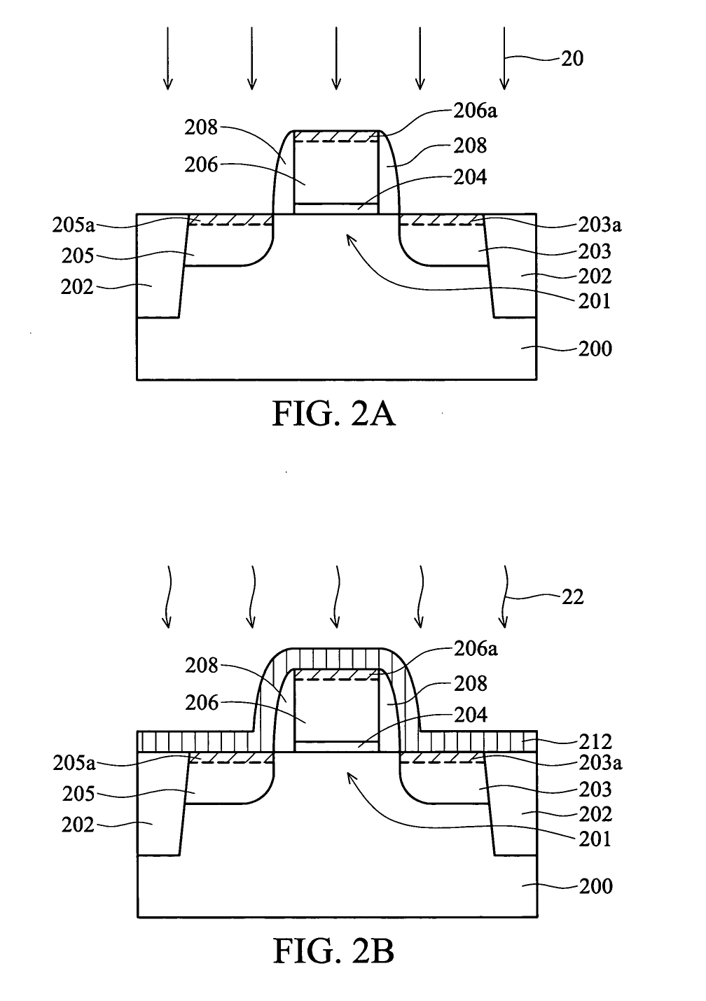

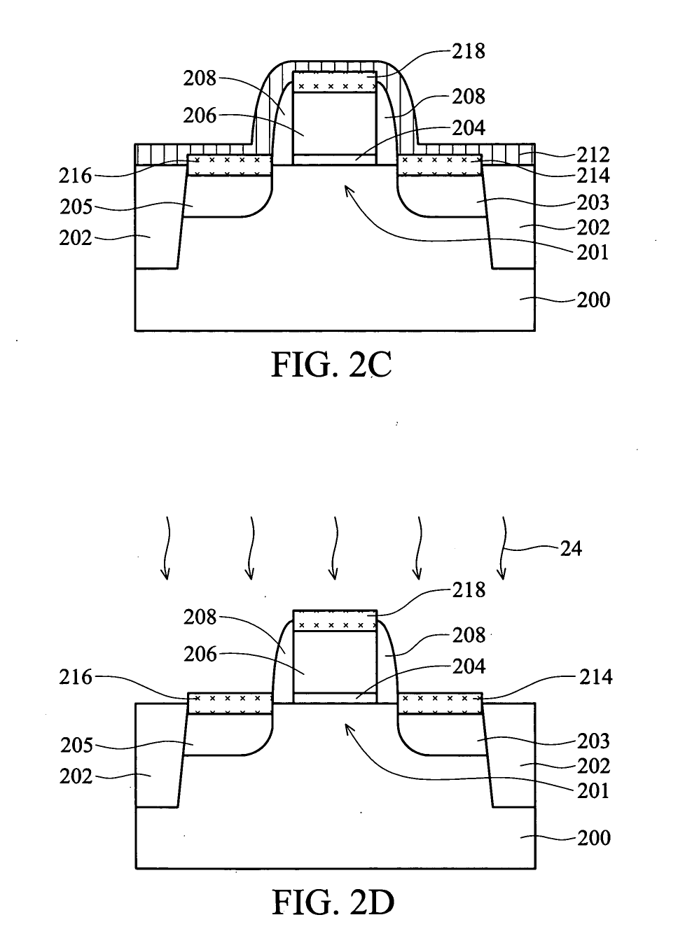

FIGS. 2A to 2D illustrate an embodiment of a self-aligned silicide (salicide) process. In FIG. 2A, a silicon or SOI substrate 200 is provided. The silicon substrate 200 may comprise crystalline silicon, polysilicon, amorphous silicon or SiGe. Moreover, the silicon substrate 200 may comprise an active region 201 defined by insulating regions 202 formed by, for example, shallow trench isolation (STI) or local oxidation of silicon (LOCOS). A semiconductor device, such as a MOS transistor is disposed on the active region 201. The device may comprise a gate dielectric layer 204 and an overlying silicon gate 206 on the active region 201. Gate spacers 208 are on both sidewalls of the silicon gate 206. Doping regions (source/drain regions) 203 and 205 are formed in the active region 201 outside the silicon gate 206.

The surfaces of the doping regions 203 and 205 of the substrate 200 and the silicon gate 206 may be optionally cleaned to remove the native oxide thereon. For example, the silicon surface is dipped into a diluted HF solution. A surface plasma treatment 20 is subsequently performed on the substrate 200. In this embodiment, the surface plasma treatment 20 is performed using N₂ or N₂O as a process gas having a flow rate of 1 sccm to 1000 sccm, thereby incorporating nitrogen into the surfaces of the doping regions 203 and 205 of the substrate 200 and the silicon gate 206 to form nitridized silicon surfaces 203a, 205a and 206a on the doping regions 203 and 205 of the substrate 200 and the silicon gate 206, respectively. The nitridized silicon surfaces 203a, 205a and 206a may be formed by RPN or DPN. The other conditions of surface plasma treatment 20 may comprise a pressure of 10 Torr to 760 Torr, a temperature of 20° C. to 400° C., a time of 0.01 sec to 600 sec, and a power of 10 W to 1000 W.

In some embodiments, nitrogen may be incorporated into the doping regions and silicon gate by ion implantation or doping. It is difficult, however, to control the implanting depth or doping depth, thus uniformity is poor. Moreover, in such methods, nitrogen may still exist in the doping region and the silicon gate after silicide formation, thus their electrical properties vary. Conversely, the surface plasma treatment is easy to control and the nitrogen can be limited to the surfaces of the doping regions and the silicon gate, providing good uniformity and preventing variation of electrical properties.

In FIG. 2B, a refractory metal layer 212, such as cobalt or nickel, is formed on the substrate 200 having the semiconductor device thereon, thereby capping the nitridized silicon surfaces 203a, 205a and 206a with the metal layer 212. The refractory metal layer 212 can be formed by conventional deposition, such as sputtering, evaporation or chemical vapor deposition (CVD). In this embodiment, the nitridized silicon surfaces 203a, 205a and 206a are capped with a cobalt layer having a thickness of 10 Å to 300 Å.

After formation of the metal layer 212, a first annealing 22, such as RPA, is performed on the substrate 200 having the metal layer 212 thereon. In this embodiment, the substrate 200 is annealed at a temperature of 200° C. to 600 ° C. for 0.01 sec to 300 sec. When the first annealing 22 is completed, the metal silicide layers 214, 216 and 218 are formed between metal layer 212 and the doping regions 203 and 205 of the substrate 200 and between the metal layer 212 and the silicon gate 206, respectively, as shown in FIG. 2C.

In FIG. 2D, the remaining metal layer 212 is subsequently removed by a suitable solution, for example, sulfuric acid or hydrogen peroxide, to expose the surface of the metal silicide layers 214, 216 and 218. Finally, a second annealing 24, such as RTA, is performed on the exposed silicide layers 214, 216 and 218, thus a stable metal silicide phase or a lower resistivity is provided. In this embodiment, the metal silicide layers 214, 216 and 218 can be cobalt silicide layers annealed at a temperature of 600° C. to 900° C. for 0.01 sec to 180 sec.

The invention provides several advantages over the conventional methods. The formation of agglomerated silicide or salicide and oxygen contamination can be suppressed by incorporating nitrogen using surface plasma treatment. The incorporated nitrogen can restrain silicide grain growth and suppress oxidization during annealing of the silicon substrate, thus the silicide layer can be stabilized. Since agglomeration is suppressed, a smooth metal/silicon interface can be achieved to reduce junction leakage current of the silicide. That is, the thermal stability and junction leakage of the silicide or salicide can be improved by nitrogen-containing plasma treatment. Moreover, since the silicide grain growth is restrained during annealing, the silicon growth does not penetrate through the overlying metal layer to cause layer inversion, thus failure of a silicide or salicide process can be prevented.

While the invention has been described by way of example and in terms of preferred embodiment, it is to be understood that the invention is not limited thereto. To the contrary, it is intended to cover various modifications and similar arrangements (as would be apparent to those skilled in the art) Therefore, the scope of the appended claims should be accorded the broadest interpretation to encompass all such modifications and similar arrangements.

What is claimed is:

1. A method for forming a silicide layer on a substrate, comprising:
providing a substrate with a silicon surface;
incorporating nitrogen into the silicon surface by a plasma treatment, to form a nitridized silicon surface;
forming a metal layer on the nitridized silicon surface;
and
annealing the substrate having the metal layer thereon to form a silicide layer between the metal layer and the substrate.

2. The method of claim 1, further comprising:
removing the metal layer on the silicide layer to expose thereof; and
annealing the exposed silicide layer.

3. The method of claim 1, further cleaning the silicon surface prior to the plasma treatment.

4. The method of claim 1, wherein the plasma treatment is performed using nitrogen as a process gas.

5. The method of claim 1, wherein the plasma treatment is performed at a pressure of 10 Torr to 760 Torr.

6. The method of claim 1, wherein the plasma treatment is performed at a temperature of 20° C. to 400° C.

7. The method of claim 1, wherein the plasma treatment is performed for 0.01 sec to 600 sec.

8. The method of claim 6, wherein the metal layer comprises nickel or cobalt.

9. A salicide process, comprising:
providing a silicon substrate comprising an active region, a silicon gate overlying the active region and a doping region in the active region outside the silicon gate;
incorporating nitrogen into the silicon gate and the doping region by a plasma treatment, to form nitridized silicon surfaces on the silicon gate and the doping region, respectively;
capping the nitridized silicon surfaces with a conformal metal layer; and
annealing the substrate having the metal layer thereon to form silicide layers between the metal layer and silicon gate and between the metal layer and the doping region, respectively.

10. The salicide process of claim 9, further comprising: removing the metal layer on the silicide layer to expose the silicide layer; and annealing the exposed silicide layer.

11. The salicide process of claim 9, further cleaning the surfaces of the silicon gate and the doping region prior to the plasma treatment.

12. The salicide process of claim 9, wherein the plasma treatment is performed using nitrogen as a process gas.

13. The salicide process of claim 9, wherein the plasma treatment is performed at a pressure of 10 Torr to 760 Torr.

14. The salicide process of claim 9, wherein the plasma treatment is performed at a temperature of 20° C. to 400° C.

15. The salicide process of claim 9, wherein the plasma treatment is performed for 0.01 sec to 600 sec.

16. The salicide process of claim 9, wherein the metal layer comprises nickel, cobalt, Pt or Ta.
